(19) United States
(12) Patent Application Publication
(10) Pub. No.: US 2013/0296689 A1
(43) Pub. Date: Nov. 7, 2013

(54) PET-MRI APPARATUS

(71) Applicants: Toshiba Medical Systems Corporation, Otawara-shi (JP); KABUSHIKI KAISHA TOSHIBA, Tokyo (JP)

(72) Inventors: Kazuya OKAMOTO, Saitama-shi (JP); Takuzo Takayama, Utsunomiya-shi (JP); Hitoshi Yamagata, Otawara-shi (JP)

(21) Appl. No.: 13/935,812

(22) Filed: Jul. 5, 2013

Related U.S. Application Data
(63) Continuation of application No. PCT/JP2012/050198, filed on Jan. 6, 2012.

(30) Foreign Application Priority Data
Jan. 6, 2011 (JP) 2011-001073

(51) Int. Cl. G01R 33/48

(52) U.S. Cl. CPC G01R 33/481
USPC 600/411

(57) ABSTRACT

A PET-MRI apparatus according to an embodiment includes a static magnetic field magnet, a gradient coil, a high-frequency coil, an MR image reconstruction unit, a PET detector, and a PET image reconstruction unit. The high-frequency coil applies a high-frequency magnetic field to a subject placed in the static magnetic field and detects a magnetic resonance signal emitted from the subject in response to application of the high-frequency magnetic field and a gradient magnetic field. The PET detector has a ring shape and detects a gamma ray emitted from a positron-emitting radionuclide injected into the subject. The coil conductor of the high-frequency coil is made up of a first high-frequency shield that covers the outer surface of the PET detector.

### CROSS-REFERENCE TO RELATED APPLICATIONS

This application is a continuation of PCT international application Ser. No. PCT/JP2012/050198 filed on Jan. 6, 2012 which designates the United States, and which claims the benefit of priority from Japanese Patent Application No. 2011-001073, filed on Jan. 6, 2011; the entire contents of which are incorporated herein by reference.

### FIELD

Embodiments described herein relate to a Positron Emission Tomography (PET)-Magnetic Resonance Imaging (MRI) apparatus.

### BACKGROUND

In recent years, examination has been conducted on creating PET-MRI devices, which are a combination of a Magnetic Resonance Imaging (MRI) device and a Positron Emission Tomography (PET) device combining. PET-MRI apparatuses are expected to be applied, for example, to head examinations and in particular to be used in diagnosing Alzheimer's disease.

A PET-MRI apparatus includes a high-frequency coil that is a component of an MRI device and a PET detector that is a component of a PET device. The high-frequency coil applies a high-frequency magnetic field to a subject and detects the magnetic resonance signal emitted from the subject in response to application of the high-frequency magnetic field and a gradient magnetic field. The PET detector detects gamma rays emitted by positron-emitting radionuclides that are injected into the subject.

With the conventional technology, however, the signal-to-noise ratio (SN ratio) of an MR image may be lowered due to interference between the high-frequency coil and the detector.

### BRIEF DESCRIPTION OF THE DRAWINGS

FIG. 1 is a diagram of a configuration of a PET-MRI apparatus according to a first embodiment.

FIG. 2 is a cross-sectional view of the internal structure of the gradient coil depicted in FIG. 1.

FIG. 3 is a diagram of a transmitting/receiving high-frequency coil and PET detectors according to the first embodiment.

FIG. 4 is a diagram of a transmitting/receiving high-frequency coil according to a second embodiment.

FIG. 5 is a diagram of a PET-MRI apparatus according to a third embodiment.

FIG. 6 is a diagram of a transmitting high-frequency coil and PET detectors according to the third embodiment.

FIG. 7 is a diagram of the appearance of the transmitting high-frequency coil according to the third embodiment.

FIG. 8 is a diagram of the appearance of a transmitting high-frequency coil according to a fourth embodiment.

FIG. 9 is a diagram of the appearance of a transmitting high-frequency coil according to a fifth embodiment.

FIG. 10 is a diagram of a cross section of a first high-frequency shield according to the fifth embodiment.

FIG. 11 is a diagram of the appearance of a transmitting high-frequency coil according to a sixth embodiment.

FIG. 12 is a diagram of the appearance of a transmitting high-frequency coil according to a seventh embodiment.

### DETAILED DESCRIPTION

A PET-MRI apparatus according to an embodiment includes a static magnetic field magnet, a gradient coil, a high-frequency coil, an MR image reconstruction unit, a PET detector, and a PET image reconstruction unit. The high-frequency coil applies a high-frequency magnetic field to a subject placed in the static magnetic field and detects a magnetic resonance signal emitted from the subject in response to application of the high-frequency magnetic field and a gradient magnetic field. The PET detector has a ring shape and detects a gamma ray emitted from a positron-emitting radionuclide injected into the subject. The coil conductor of the high-frequency coil is made up of a first high-frequency shield that covers the outer surface of the PET detector.

### First Embodiment

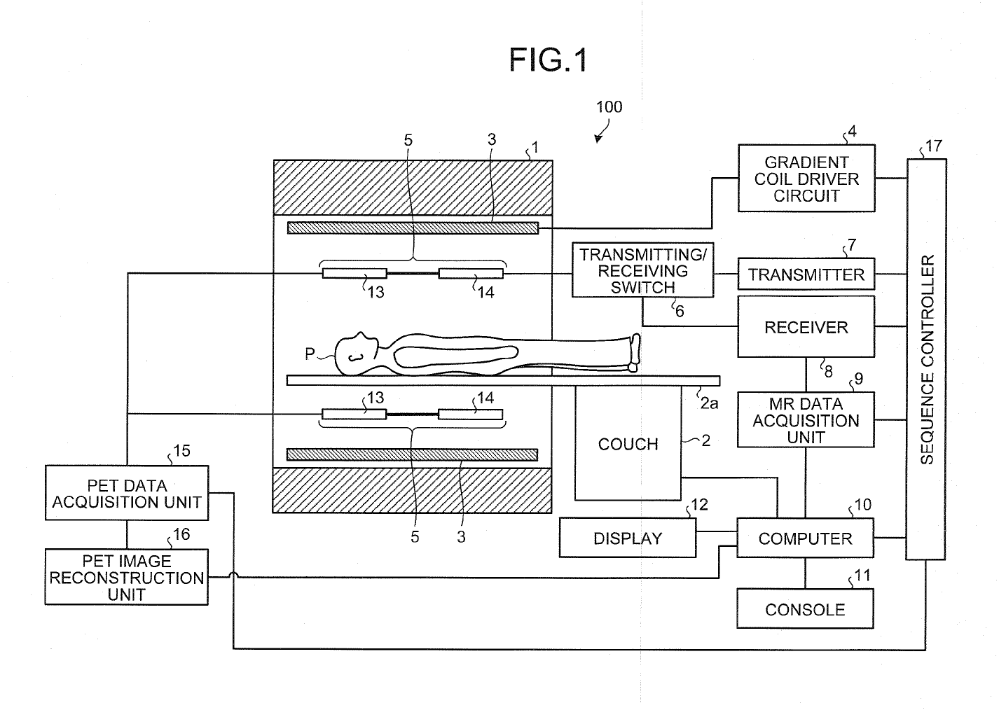

First, a first embodiment will be described. FIG. 1 is a diagram of a configuration of a PET-MRI apparatus 100 according to the first embodiment. As depicted in FIG. 1, the PET-MRI apparatus 100 includes a static magnetic field magnet 1, a couch 2, a gradient coil 3, a gradient coil driver circuit 4, a transmitting/receiving high-frequency coil 5, a transmitting/receiving switch 6, a transmitter 7, a receiver 8, an MR data acquisition unit 9, a computer 10, a console 11, a display 12, PET detectors 13 and 14, a PET data acquisition unit 15, a PET image reconstruction unit 16, and a sequence controller 17.

The static magnetic field magnet 1 generates a static magnetic field in an approximately cylindrical bore. The bore is the space formed on the inner circumferential side of the static magnetic field magnet 1 and in which the subject P is arranged when the PET-MRI apparatus 100 performs imaging. The couch 2 includes a couchtop 2a on which a subject P is set. When imaging is performed, the couch 2 moves the subject P into a static magnetic field by moving the couchtop 2a into the bore.

The gradient coil 3 applies, to the subject P, gradient magnetic fields Gx, Gy, and Gz, whose magnetic field intensities change linearly in the X, Y, and Z directions. The gradient coil 3 is formed to be approximately cylindrical and is arranged on the inner circumferential side of the static magnetic field magnet 1. The gradient coil driver circuit 4 drives the gradient coil 3 under the control of the sequence controller 17.

The transmitting/receiving high-frequency coil 5 applies to the subject P, who is positioned in the static magnetic field, a high-frequency magnetic field in accordance with a high-frequency pulse transmitted from the transmitting/receiving switch 6. The transmitting/receiving high-frequency coil 5 detects a magnetic resonance signal that is emitted from the subject P in response to application of a high-frequency magnetic field and a gradient magnetic field and transmits the detected magnetic resonance signal to the transmitting/receiving switch 6. The transmitting/receiving high-frequency coil 5 is arranged on the inner circumferential side of the gradient coil 3.

In the first embodiment, the transmitting/receiving high-frequency coil 5 is a bird cage coil formed to be approximately cylindrical and including two end rings and multiple rungs. The end ring is a coil conductor that is formed in a ring and the rung is a coil conductor that is formed as a rod. The two end rings are arranged such that the ring surfaces are opposed to each other. The rungs are arranged such that each of the rungs extends between the end rings, and the rungs are arrayed at approximately equal intervals in the circumferential direction of each of the end rings. The transmitting/receiving high-frequency coil 5 will be described in detail below.

The transmitting/receiving switch 6 switches the operation of the transmitting/receiving high-frequency coil 5 between transmitting and receiving under the control of the sequence controller 17. When transmitting is performed, the transmitting/receiving switch 6 transmits, to the transmitting/receiving high-frequency coil 5, a high-frequency pulse transmitted from the transmitter 7. When receiving is performed, the transmitting/receiving switch 6 transmits, to the receiver 8, a magnetic resonance signal detected by the transmitting/receiving high-frequency coil 5.

The transmitter 7 transmits a high-frequency pulse to the transmitting/receiving high-frequency coil 5 via the transmitting/receiving switch 6 under the control of the sequence controller 17. Under the control of the sequence controller 17, the receiver 8 receives a magnetic resonance signal from the transmitting/receiving high-frequency coil 5 via the transmitting/receiving switch 6 and transmits the received magnetic resonance signal to the MR data acquisition unit 9.

Under the control of the sequence controller 17, the MR data acquisition unit 9 acquires the magnetic resonance signal transmitted from the receiver 8. The MR data acquisition unit 9 amplifies and detects the acquired magnetic resonance signal, performs A/D conversion on the magnetic resonance signal, and then transmits the magnetic resonance signal, which is converted to a digital signal, to the computer 10. The computer 10 is controlled by the console 11 and reconstructs an MR image on the basis of the magnetic resonance signal transmitted from the MR data acquisition unit 9. The computer 10 displays the reconstructed MR image on the display 12.

Each of the PET detectors 13 and 14 is formed in a ring and detects, as counted information, gamma rays (including annihilation radiation) that are emitted by positron-emitting radionuclides that are injected into the subject P. The PET detectors 13 and 14 transmit the detected counted information to the PET data acquisition unit 15. Each of the PET detectors 13 and 14 are made by arranging, in a ring, multiple semiconductor detectors that convert gamma rays to analog signals to detect the gamma rays by using semiconductor devices. The PET detectors 13 and 14 are arranged such that the magnetic field center of the static magnetic field, which is generated by the static magnetic field magnet 1, is between the PET detectors 13 and 14.

In the first embodiment, each of the PET detectors 13 and 14 is covered with a first high-frequency shield. The high-frequency shield that covers the outer surface of the PET detector 13 and the high-frequency shield that covers the outer surface of the PET detector 14 form the two end rings of the transmitting/receiving high-frequency coil 5. The PET detectors 13 and 14 will be described in detail below.

The PET data acquisition unit 15 generates simultaneous counted information under the control of the sequence controller 17. By using the counted information on gamma rays that are detected by the PET detector 13, the PET data acquisition unit 15 generates, as simultaneous counted information, a combination of counted information on simultaneous detection of the gamma rays emitted by a positron-emitting radionuclide.

The PET image reconstruction unit 16 reconstructs a PET image by using, as projection data, the simultaneous counted information that is generated by the PET data acquisition unit 15. The PET image that is reconstructed by the PET image reconstruction unit 16 is transmitted to the computer 10 and is then displayed on the display 12. The sequence controller 17 receives information on various sequences, which are executed when imaging is performed, from the computer 10 and controls each unit.

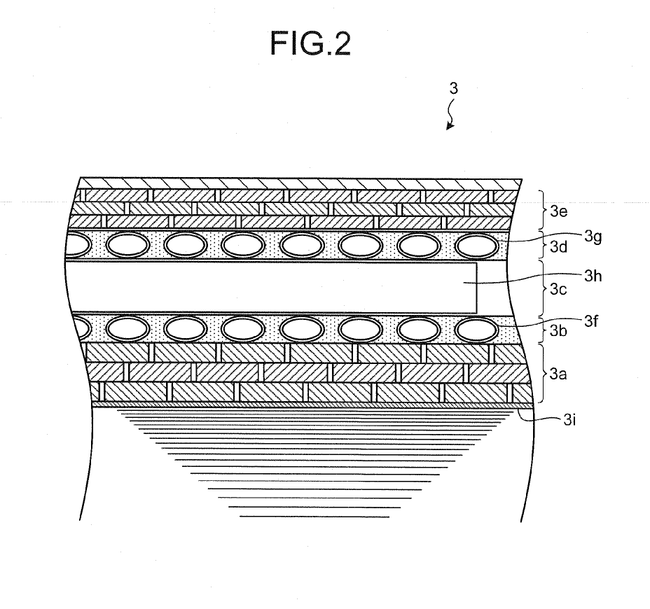

The internal structure of the gradient coil 3 depicted in FIG. 1 will be described below. FIG. 2 is a cross-sectional view of the internal structure of the gradient coil 3 depicted in FIG. 1. In FIG. 2, the upper side shows the outer side of the cylinder of the gradient coil and the lower side shows the inner side of the cylinder. As depicted in FIG. 2, the gradient coil 3 is made by sequentially superposing a main coil 3a, a main coil side cooling layer 3b, a shim tray insertion guide layer 3c, a shield coil side cooling layer 3d, and a shield coil 3e from the inner side (lower side in FIG. 2) of the cylinder toward the outer side (upper side in FIG. 2) of the cylinder.

The main coil side cooling layer 3b is provided with a main coil side cooling tube 3f mainly for cooling the main coil 3a. The shield coil side cooling layer 3d is provided with a shield coil side cooling tube 3g mainly for cooling the shield coil 3e. The main coil side cooling tube 3f and the shield coil side cooling tube 3g are formed in helix so as to suit the cylindrical shape of the gradient coil 3. Multiple shim trays 3h each housing multiple iron shims are inserted into the shim tray insertion guide layer 3c.

Furthermore, a second high-frequency shield 3i is provided on the inner circumferential side of the main coil 3a. The second high-frequency shield 3i is arranged between the gradient coil 3 and the transmitting/receiving high-frequency coil 5 and thus shields any high frequency that is generated by the transmitting/receiving high-frequency coil 5. By arranging the second high-frequency shield 3i as described above, coupling between the high frequency, which is generated by the transmitting/receiving high-frequency coil 5, and the gradient coil 3 can be prevented.

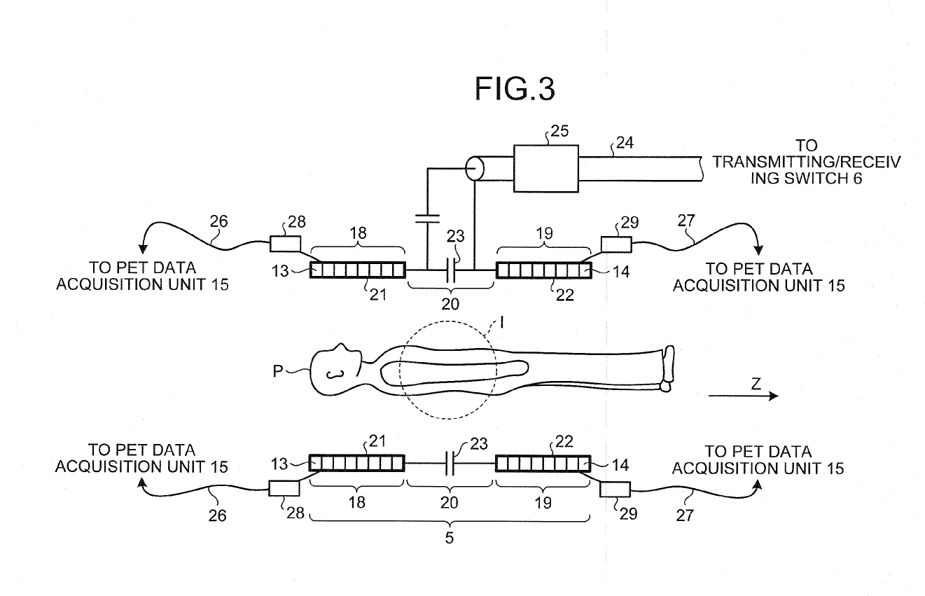

The details of the transmitting/receiving high-frequency coil 5 and the PET detectors 13 and 14 according to the first embodiment will be descried below. FIG. 3 is a diagram of the transmitting/receiving high-frequency coil 5 and the PET detectors 13 and 14 according to the first embodiment. FIG. 3 shows a cross section including the axis of each of the transmitting/receiving high-frequency coil 5, which is formed to be approximately cylindrical, and the PET detectors 13 and 14.

The transmitting/receiving high-frequency coil 5 includes coil conductors that generate a high-frequency magnetic field to be applied to the subject P and detects a magnetic resonance signal emitted from the subject P. Specifically, as depicted in FIG. 3, the transmitting/receiving high-frequency coil 5 includes an end ring 18, an end ring 19, and multiple rungs 20 as the coil conductors.

The end rings 18 and 19 are each a coil conductor formed in a ring and are arranged such that the ring surfaces are opposed to each other in the Z direction. Each of the rungs 20 is a coil conductor, which is formed as a rod, and each of the rungs 20 connects between the end ring 18 and the end ring 19. Each rung 20 is arranged so as to extend between the end ring 18 and the end ring 19, and the rungs 20 are arrayed at approximately equal intervals in the circumferential direction of the end rings 18 and 19.

In the first embodiment, the end ring 18 is made up of a first high-frequency shield 21 that is formed so as to cover the outer surface of the PET detector 13. In other words, in the first embodiment, the end ring 18 is made by surrounding the PET detector 13, which is formed in a ring, with the first high-frequency shield 21 that is made from a conductor, such as copper plate. Similarly, the end ring 19 is made up from a first high-frequency shield 22, which is formed so as to cover the outer surface of the PET detector 14.

As described above, by surrounding the PET detectors 13 and 14 with the first high-frequency shields, respectively, noise generated by the PET detector 13 can be prevented from being mixed with the receiving system that receives a magnetic resonance signal. Furthermore, the PET detectors 13 and 14 can be prevented from degrading the efficiency of the transmitting/receiving high-frequency coil 5. Furthermore, the high-frequency transmitted by the transmitting/receiving high-frequency coil 5 can be prevented from having negative effects on the PET detectors 13 and 14.

Furthermore, as depicted in FIG. 3, the transmitting/receiving high-frequency coil 5 according to the first embodiment includes a capacitor 23, a transmitting/receiving cable 24, a high-frequency shield circuit 25, a signal and control line 26, a signal and control line 27, and high-frequency shield circuits 28 and 29.

The capacitor 23 is inserted into approximately the center part of each of the rungs 20. The capacitor 23 adjusts the transmitting/receiving high-frequency coil 5 so as to generate a uniform high-frequency magnetic field at a desired frequency in an imaging area I that is formed on the inner circumferential side of the transmitting/receiving high-frequency coil 5. In other words, the transmitting/receiving high-frequency coil 5 is a low-pass bird cage coil.

The transmitting/receiving cable 24 has one end connected to the capacitor 23 and the other end connected to the transmitting/receiving switch 6. The transmitting/receiving cable 24 transfers the high-frequency pulse, which is transmitted from the transmitting/receiving switch 6, to the transmitting/receiving high-frequency coil 5. The transmitting/receiving cable 24 transfers the magnetic resonance signal, which is detected by the transmitting/receiving high-frequency coil 5, to the transmitting/receiving switch 6. As the transmitting/receiving cable 24, for example, a coaxial cable is used. Furthermore, the high-frequency shield circuit 25 is connected to the transmitting/receiving cable 24.

The signal and control line 26 has one end connected to the PET detector 13 and the other end connected to the PET data acquisition unit 15. The signal and control line 26 transfers the counted information, which is detected by the PET detector 13, to the PET data acquisition unit 15. The signal and control line 26 is shielded to avoid interference with the transmitting/receiving high-frequency coil 5. The high-frequency shield circuit 28 is connected to the signal and control line 26.

The signal and control line 27 has one end connected to the PET detector 14 and the other end connected to the PET data acquisition unit 15. The signal and control line 27 transfers the counted information, which is detected by the PET detector 14, to the PET data acquisition unit 15. The signal and control line 27 is shielded to avoid interference with the transmitting/receiving high-frequency coil 5. The high-frequency shield circuit 29 is connected to the signal and control line 27.

As described above, in the first embodiment, the transmitting/receiving high-frequency coil 5 includes the end rings 18 and 19. The end ring 18 is made up of the first high-frequency shield 21 that covers the outer surface of the PET detector 13, and the end ring 19 is made up of the first high-frequency shield 22 that covers the outer surface of the PET detector 14. In other words, in the first embodiment, by covering the ring-shaped PET detectors 13 and 14 with the first high-frequency shields 21 and 22, respectively, the coil conductors of the transmitting/receiving high-frequency coil 5 are formed. Thus, according to the first embodiment, interference between the transmitting/receiving high-frequency coil 5 and the PET detector 13 and interference between the transmitting/receiving high-frequency coil 5 and the PET detector 14 can be reduced, which improves the SN ratio of the MR image.

### Second Embodiment

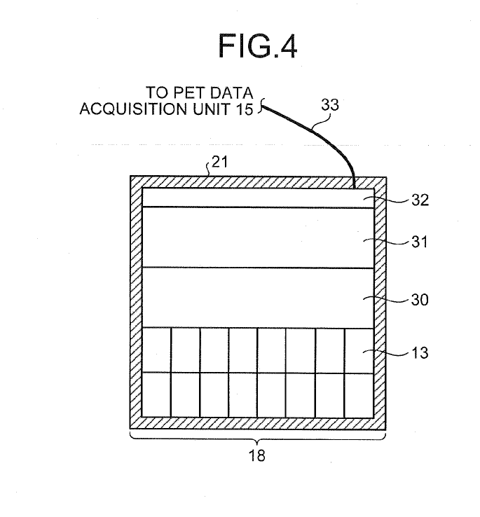

A second embodiment will be described below. The second embodiment relates to the transmitting/receiving high-frequency coil 5 that is described in the first embodiment. FIG. 4 is a diagram of the transmitting/receiving high-frequency coil 5 according to the second embodiment. FIG. 4 shows a cross section of the end ring 18 among the two end rings of the transmitting/receiving high-frequency coil 5. As depicted in FIG. 4, in the second embodiment, the PET-MRI apparatus 100 includes, in addition to the PET detector 13, a preamplifier 30, an A/D converter 31, an I/O interface 32, and an optical fiber 33.

The PET detector 13 converts a gamma ray to an analog signal by using the semiconductor detector and outputs the analog signal. The preamplifier 30 is a signal amplifier that amplifies the analog signal, which is output from the PET detector 13. The A/D converter 31 is a first signal converter that converts the analog signal, which is amplified by the preamplifier 30, to a digital signal.

The I/O interface 32 is a second signal converter that converts the digital signal, which is obtained by the A/D converter 31, to an optical signal. The optical fiber 33 has one end connected to the I/O interface 32 and the other end connected to the PET data acquisition unit 15. The optical fiber 33 is used as the signal and control line 26 described in the first embodiment.

In the second embodiment, the first high-frequency shield 21 is formed so as to cover, in addition to the PET detector 13, the preamplifier 30, the A/D converter 31, and the I/O interface 32. Accordingly, the noise generated by the semiconductor detectors of the PET detector 13 can be shielded. Furthermore, because the signal detected by the PET detector 13 is transferred via the optical fiber, noise caused due to the digital signal can be prevented.

### Third Embodiment

A third embodiment will be described below. In the first embodiment, a case is described where the PET-MRI apparatus 100 includes the transmitting/receiving high-frequency coil 5 that is a high-frequency coil for both transmitting and receiving. In the third embodiment, a case will be described where a PET-MRI apparatus includes a transmitting high-frequency coil and a receiving high-frequency coil.

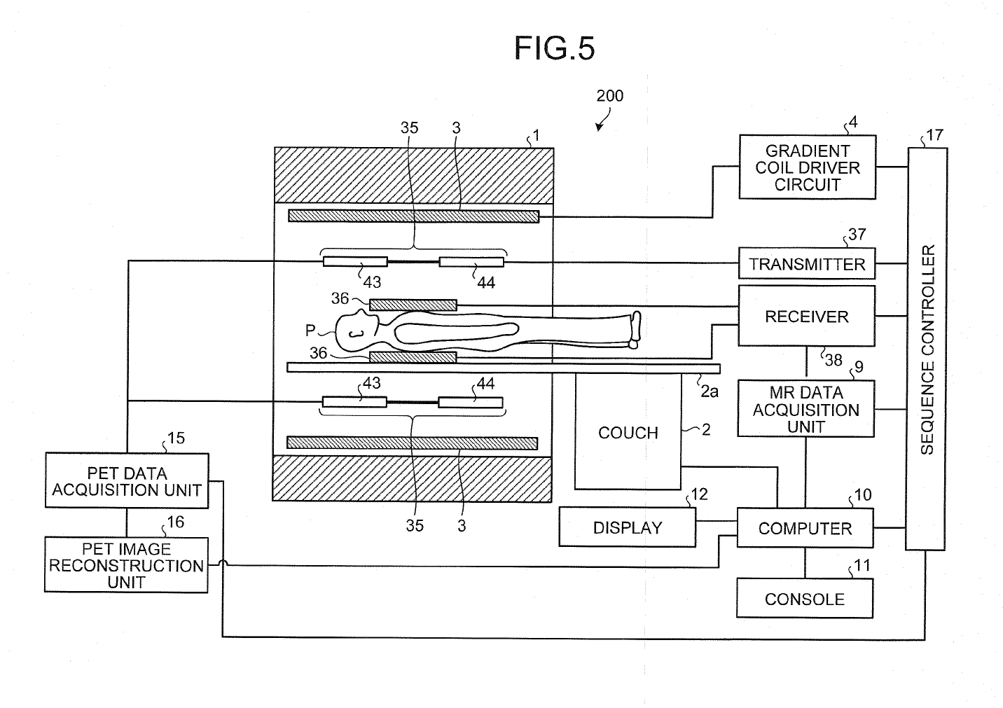

FIG. 5 is a diagram of a configuration of a PET-MRI apparatus 200 according to the third embodiment. As depicted in FIG. 5, the PET-MRI apparatus 200 includes the static magnetic field magnet 1, the couch 2, the gradient coil 3, the gradient coil driver circuit 4, a transmitting high-frequency coil 35, a receiving high-frequency coil 36, a transmitter 37, a receiver 38, the MR data acquisition unit 9, the computer 10, the console 11, the display 12, PET detectors 43 and 44, the PET data acquisition unit 15, the PET image reconstruction unit 16, and the sequence controller 17. The static magnetic field magnet 1, the couch 2, the gradient coil 3, the gradient coil driver circuit 4, the MR data acquisition unit 9, the computer 10, the console 11, the display 12, the PET data acquisition unit 15, the PET image reconstruction unit 16, and the sequence controller 17 are the same as those of the first embodiment and therefore descriptions thereof will be omitted.

In accordance with a high-frequency pulse transmitted from the transmitter 37, the transmission high-frequency coil 35 applies a high-frequency magnetic field to the subject P, who is positioned in a static magnetic field. The transmission high-frequency coil 35 is arranged on the inner circumferential side of the gradient coil 3.

In the third embodiment, the transmitting high-frequency coil 35 is a bird cage coil formed to be approximately cylindrical and includes two end rings and multiple rungs. The end ring is a coil conductor formed in a ring and the rung is a coil conductor formed as a rod. The two end rings are arranged such that the ring surfaces are opposed to each other. The rungs are arranged such that each of the rungs extends between the end rings, and the rungs are arrayed at approximately equal intervals in the circumferential direction of each of the end rings. The transmitting high-frequency coil 35 will be described in detail below.

The receiving high-frequency coil 36 detects a magnetic resonance signal, which is emitted from the subject P in response to the application of a high-frequency magnetic field and a gradient magnetic field, and transmits the detected magnetic resonance signal to the receiver 38. The receiving high-frequency coil 36 is, for example, a surface coil arranged on the surface of the subject P depending on the region to be imaged. For example, when a body part of the subject P is imaged, the two receiving high-frequency coils 36 are arranged above and below the subject P.

The transmitter 37 transmits a high-frequency pulse to the transmitting high-frequency coil 35 under the control of the sequence controller 17. The receiver 38 receives a magnetic resonance signal from the receiving high-frequency coil 36 under the control of the sequence controller 17. The receiver 38 transmits the received magnetic resonance signal to the MR data acquisition unit 9.

Each of the PET detectors 43 and 44 is formed in a ring and detects, as counted information, gamma rays (including annihilation radiation) that are emitted by the positron-emitting radionuclides injected into the subject P. The PET detectors 43 and 44 transmit the detected counted information to the PET data acquisition unit 15. The PET detectors 43 and 44 are formed by arranging, in a ring, multiple semiconductor detectors that convert gamma rays into analog signals and the PET detectors 43 and 44 detect the gamma rays by using semiconductor devices. The PET detectors 43 and 44 are arranged apart from each other in the axial direction of the static magnetic field magnet 1 on the inner circumferential side of the gradient coil 3. Furthermore, the PET detectors 43 and 44 are arranged such that the magnetic field center of the static magnetic field, which is generated by the static magnetic field magnet 1, is between the PET detectors 43 and 44.

In the third embodiment, the PET detectors 43 and 44 are covered with first high-frequency shields, respectively. The first high-frequency shield that covers the outer surface of the PET detector 43 and the first high-frequency shield that covers the outer surface of the PET detector 44 make up the two end rings of the transmitting high-frequency coil 35. The PET detectors 43 and 44 will be described in detail below.

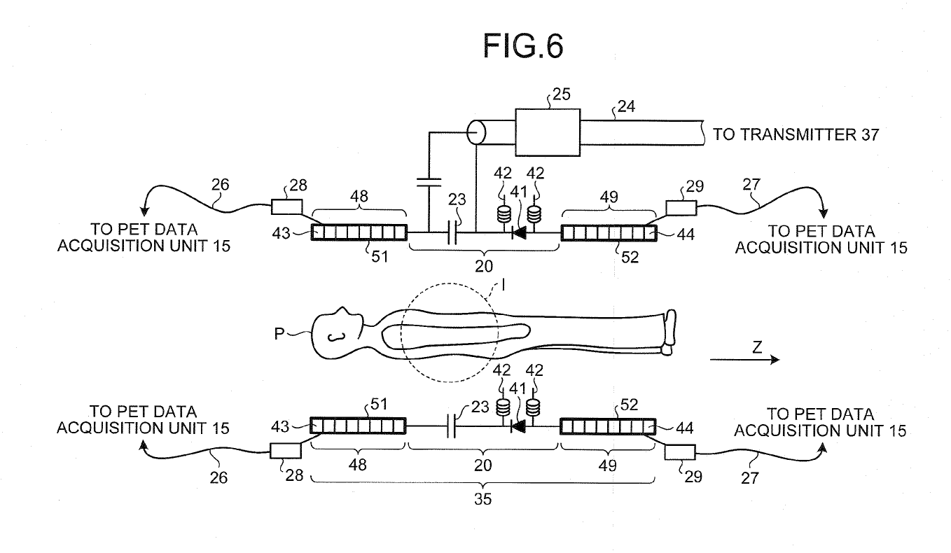

The transmitting high-frequency coil 35 and the PET detectors 43 and 44 according to the third embodiment will be described in detail below. FIG. 6 is a diagram of the transmitting high-frequency coil 35 and the PET detectors 43 and 44 according to the third embodiment. FIG. 6 shows a cross section including the axis of each of the transmitting high-frequency coil 35, which is formed to be approximately cylindrical, and the PET detectors 43 and 44.

The transmitting high-frequency coil 35 includes coil conductors that generate a high-frequency magnetic field that is applied to the subject P. Specifically, as depicted in FIG. 6, the transmitting high-frequency coil 35 includes an end ring 48, an end ring 49, and the multiple rungs 20 as the coil conductors.

The end rings 48 and 49 are each a coil conductor formed in a ring and are arranged such that the ring surfaces are opposed to each other in the Z direction. Each of the rungs 20 is a coil conductor, which is formed as a rod, and each of the rungs 20 connects between the end ring 48 and the end ring 49. Each of the rungs 20 is arranged so as to extend between the end ring 48 and the end ring 49, and the rungs 20 are arrayed at approximately equal intervals in the circumferential direction of the end rings 48 and 49.

In the third embodiment, the end ring 48 is made up of a first high-frequency shield 51 that is formed so as to cover the outer surface of the PET detector 43. In other words, in the third embodiment, the end ring 48 is made by surrounding the PET detector 43, which is formed in a ring, with the first high-frequency shield 51, which is made from a conductor, such as a copper plate. Similarly, the end ring 49 is made up of a high-frequency shield 52, which is formed so as to cover the outer surface of the PET detector 44.

As described above, by surrounding the PET detectors 43 and 44 with the first high-frequency shields, respectively, noises generated from the PET detectors 43 and 44 can be prevented from being mixed into the receiving system that receives a magnetic resonance signal. Furthermore, the PET detectors 43 and 44 can be prevented from degrading the efficiency of the transmitting high-frequency coil 35. Furthermore, the high frequency transmitted by the transmitting high-frequency coil 35 can be prevented from having a negative effect on the PET detectors 43 and 44.

Furthermore, as depicted in FIG. 6, the transmitting high-frequency coil 35 according to the third embodiment includes the capacitor 23, the transmitting/receiving cable 24, the high-frequency shield circuit 25, the signal and control line 26, the signal and control line 27, and the high-frequency shield circuits 28 and 29. The capacitor 23, the transmitting/receiving cable 24, the high-frequency shield circuit 25, the signal and control line 26, the signal and control line 27, and the high-frequency shield circuits 28 and 29 are the same as those in the first embodiment and therefore descriptions thereof will be omitted. In the third embodiment, however, the transmitting/receiving cable 24 has one end connected to the capacitor 23 and the other end connected to the transmitter 37 and transfers the high-frequency pulse, which is transmitted from the transmitter 37, to the transmitting high-frequency coil 35.

The transmitting high-frequency coil 35 is different from the transmitting/receiving high-frequency coil 5 in that the transmitting high-frequency coil 35 includes, in the rung 20, a switch that switches to a desired synchronization state when transmitting and switches to a non-synchronization state when receiving. The switch is made of, for example, a PIN diode 41 and a choke power supply cable 42.

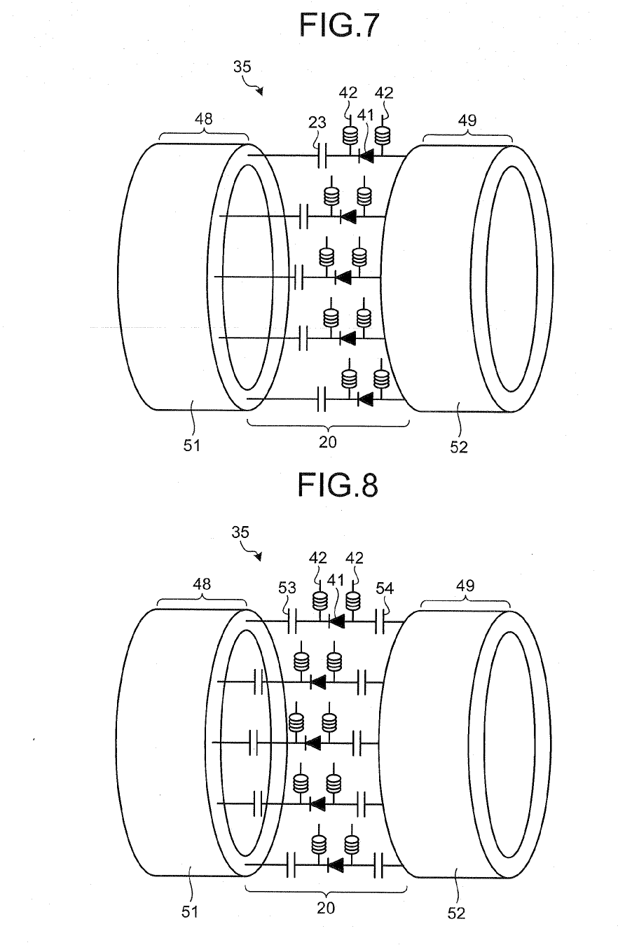

FIG. 7 is a diagram of the appearance of the transmitting high-frequency coil 35 according to the third embodiment. As depicted in FIG. 7, the PIN diode 41 is inserted linearly into the rung 20. The choke power supply cable 42 is connected to both ends of the PIN diode 41 and powers the PIN diode 41.

When transmitting, a current flows forward in the PIN diode 41 via the choke power supply cable 42 and thus the PIN diode 41 enters an ON state and the transmitting high-frequency coil 35 enters a synchronization state. In contrast, when receiving, a reverse voltage is applied to the PIN diode 41 via the choke power supply cable 42 and thus the PIN diode enters an OFF state and the transmitting high-frequency coil 35 enters a non-synchronization state. Accordingly, the receiving high-frequency coil 36 can receive a magnetic resonance signal.

As described above, in the third embodiment, the transmitting high-frequency coil 35 includes the end rings 48 and 49. The end ring 48 is made up of the first high-frequency shield 51 that covers the outer surface of the PET detector 43 and the end ring 49 is made up of the first high-frequency shield 52 that covers the outer surface of the PET detector 44. In other words, in the third embodiment, the coil conductors of the transmitting high-frequency coil 35 are made by covering the ring-shaped PET detectors 43 and 44 with the first high-frequency shields 51 and 52, respectively. Thus, according to the third embodiment, interference between the transmitting high-frequency coil 35 and the PET detector 43 and the interference between the transmitting high-frequency coil 35 and the PET detector 44 can be reduced, which improves the SN ratio of the MR image.

In the third embodiment, a case is described where the transmitting high-frequency coil 35 includes the end ring. The receiving high-frequency coil 36 may include a ring-shaped coil conductor that is arranged so as to surround the subject P. In this case, as the ring-shaped coil conductor of the receiving high-frequency coil 36, a PET detector covered with a first high-frequency shield may be used. In other words, in the third embodiment, at least one of the coil conductor of the transmitting high-frequency coil 35 and the coil conductor of the receiving high-frequency coil 36 is made up of the first high-frequency shield that covers the outer surface of the PET detector.

### Fourth Embodiment

A fourth Embodiment will be described here. The fourth embodiment relates to the transmitting high-frequency coil 35 described in the third embodiment. FIG. 8 is a diagram of the appearance of the transmitting high-frequency coil 35 according to the fourth embodiment. As depicted in FIG. 8, in the transmitting high-frequency coil in the fourth embodiment, a switch including the PIN diode 41 and the choke power supply cable 42 is arranged at approximately the center of the rung 20.

Furthermore, in the fourth embodiment, two capacitors 53 and 54 are arranged at symmetrical positions with respect to the switch. It is satisfactory if the power for transmitting be supplied from both ends of one of the capacitors 53 and 54 or both ends between which there are the capacitors 53 and 54. As described above, in the fourth embodiment, the symmetry of the transmitting high-frequency coil 35 with respect to the switch can be ensured. As a result, the position of the switch is at an equipotential surface and thus no load is applied to the choke. Accordingly, the electric adjustment can be performed easily.

### Fifth Embodiment

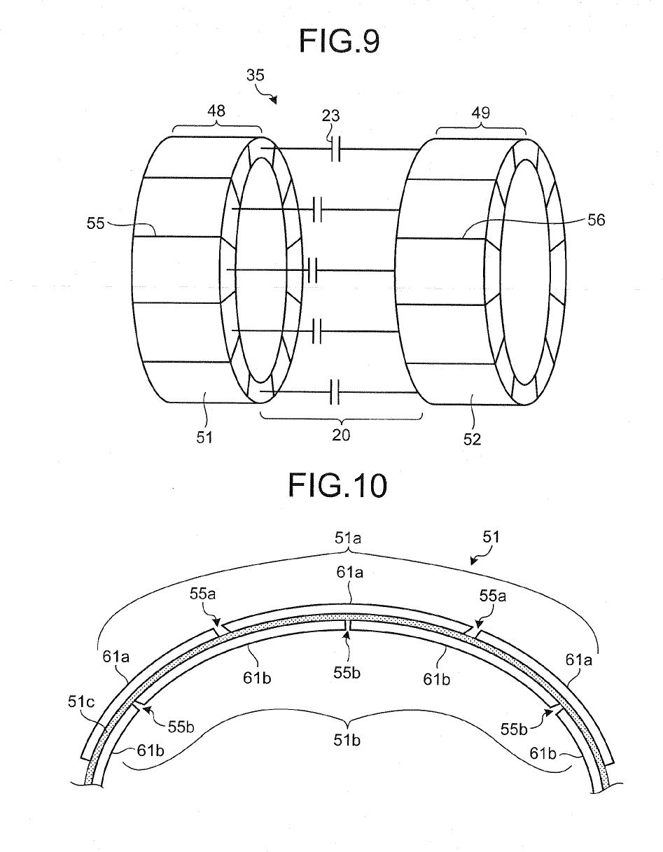

A fifth embodiment will be described here. The fifth embodiment relates to the transmitting high-frequency coil 35 described in the third embodiment. In the fifth embodiment, in the transmitting high-frequency coil 35, each of the first high-frequency shields 51 and 52 includes slits (gaps). FIG. 9 is a diagram of the appearance of the transmitting high-frequency coil 35 according to the fifth embodiment. For example, as depicted in FIG. 9, multiple slits 55 that divide the first high-frequency shield 51 into multiple conductors along the circumferential direction of the first high-frequency shield 51 are formed in the first high-frequency shield 51. Similarly, multiple slits 56 are formed in the first high-frequency shield 52.

Accordingly, in each of the first high-frequency shields, no DC current flows between the multiple conductors that are divided along the circumferential direction. In other words, each of the multiple conductors divided in the circumferential direction is insulated from a DC (Direct Current). As a result, when MR imaging is performed, any eddy current that is induced, on the surface of the first high-frequency shield 51 due to a gradient magnetic field can be reduced, which prevents image degradation caused by an eddy current magnetic field.

For the first high-frequency shields 51 and 52, while it is required to reduce the occurrence of eddy currents, it is also required to shield a desired high frequency. FIG. 10 is a diagram of a cross section of the first high-frequency shield 51 according to the fifth embodiment. For example, as depicted in FIG. 10, the first high-frequency shield 51 is made by arranging a dielectric 51c between an outer shield member 51a and an inner shield member 51b.

Multiple slits 55a are formed in the outer shield member 51a and the slits 55a divide the outer shield member 51a into multiple conductors 61a. Similarly, multiple slits 55b are formed in the inner shield member 51b and the slits 55b divide the outer shield member 51b into multiple conductors 61b. The outer shield member 51a and the inner shield member 51b are arranged such that the position of each slit is out of alignment along the circumferential direction of the first high-frequency shield 51.

Because of such an arrangement, a part where the conductor 61a and the conductor 61b, between which there is the dielectric 51c, functions as a capacitive device. By sufficiently reducing the thickness of the dielectric 51c, the first high-frequency shield 51 can enter a state where the impedance is significantly low with respect to a desired frequency, i.e., a state close to a conductive state. Because each of the multiple conductors 61a and 61b is DC-insulated by the slits 55a and 55b, the occurrence of an eddy current on the surface of the first high-frequency shield 51 can be reduced.

As described above, according to the fifth embodiment, while the occurrence of an eddy current on the surface of the first high-frequency shield 51 is reduced, the desired frequency can still be shielded.

### Sixth Embodiment

A sixth embodiment will be described below. In the sixth embodiment, a case is described where the PET-MRI apparatus 200 described in the third embodiment includes cooling units that are provided on the outer surfaces of the first high-frequency shields 51 and 52. Semiconductor detectors that are used in a PET detector are generally thermally sensitive. However, the preamplifier and A/D converter generally generate heat in a conductive state. Transfer of heat, which is generated by the preamplifier and the A/D converter, to the semiconductor detectors via the first high-frequency shields 51 and 52 may deteriorate their characteristics. In the sixth embodiment, by providing the first high-frequency shields 51 and 52 with cooling units, the heat generated by the preamplifier and the A/D converter can be released.

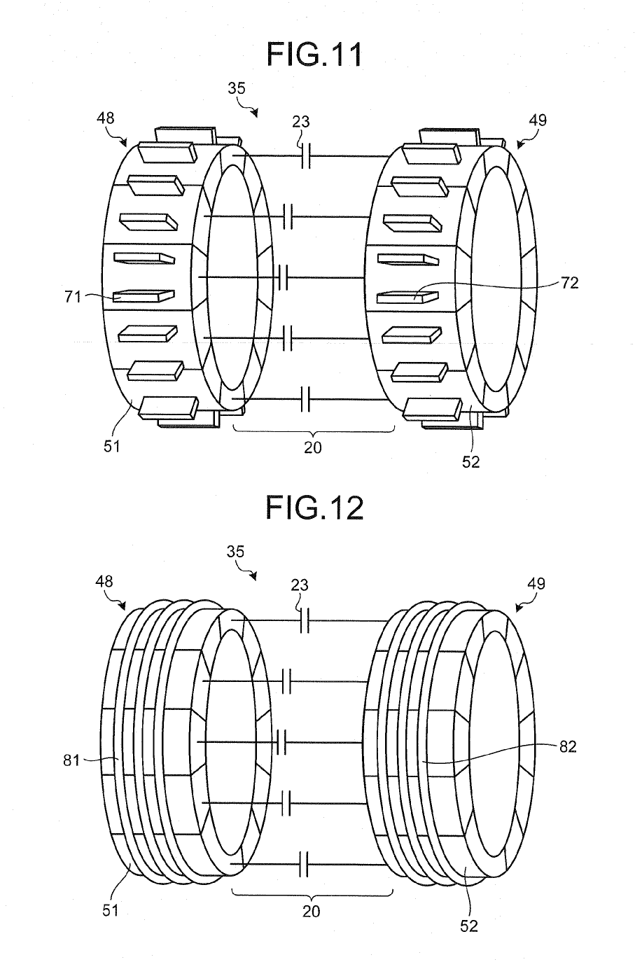

FIG. 11 is a diagram of the appearance of the transmitting high-frequency coil 35 according to the sixth embodiment. For example, as depicted in FIG. 11, multiple heat dissipating fins 71 are provided as a cooling unit on the outer circumference of the first high-frequency shield 51. Each of the heat dissipating fins 71 is made of a plate member and is provided so as to project from the outer surface of the first high-frequency shield 51. The heat dissipating fins 71 are arranged at predetermined intervals in the circumferential direction of the first high-frequency shield 51. Similarly, multiple heat dissipating fins 72 are provided on the outer circumference of the first high-frequency shield 52.

As described above, according to the sixth embodiment, by providing the heat dissipating fins 71 and 72 on the outer circumferences of the first high-frequency shields 51 and 52, the heat generated by the preamplifier and the A/D converter can be released. In general, an MRI device is provided with a mechanism for ventilating the bore in which the transmitting high-frequency coil 35 is arranged. The wind generated by the mechanism makes contact with the heat dissipating fins 71 and 72, which improves the cooling effect.

### Seventh Embodiment

A seventh embodiment will be described below. In the seventh embodiment, a case is described where the PET-MRI apparatus 200 described in the third embodiment includes a further cooling unit other than the heat dissipating fins 71 and 72.

FIG. 12 is a diagram of the appearance of the transmitting high-frequency coil 35 according to the seventh embodiment. As depicted in FIG. 12, for example, a cooling pipe 81 is provided as a cooling unit along the outer circumference of the first high-frequency shield 51. The cooling pipe is arranged so as to make contact with the outer circumference of the first high-frequency shield 51. Similarly, a cooling pipe 82 is provided on the outer circumference of the first high-frequency shield 52. By passing a coolant (e.g., water) at a certain temperature through the cooling pipes 81 and 82, the heat generated in the end rings 48 and 49 can be removed. The cooling pipes may be provided on the inner side of the first high-frequency shields. In this case, for example, the cooling pipes are arranged away from the inner circumference of the first high-frequency shield such that the heat generated from the first high-frequency shield into the bore is reduced. Alternatively, the cooling pipes may be arranged so as to make contact with the inner circumference of the first high-frequency shield. As described above, by arranging the cooling pipes on the inner side of the first high-frequency shields, the transfer of the heat generated from the inner circumferences of the first high-frequency shields to the subject can be reduced.

The first to seventh embodiments are described independently, but each of the embodiments can be carried out in combination. For example, the configuration of the transmitting/receiving high-frequency coil 5 described in the second embodiment can be applied to the transmitting high-frequency coil 35 described in the third embodiment. For example, the cooling unit described in the sixth and seventh embodiments may be applied to the PET-MRI apparatus 100 according to the first embodiment.

In the above-described embodiments, a case is described where the PET detectors that are covered with the first high-frequency shields are used as the two end rings of the high-frequency coil. However, in order to generate a PET image, it is not necessary to provide two PET detectors. Thus, in a case where only one PET detector is provided, a PET detector covered with a first high-frequency shield may be used for only one of the two end rings of the high-frequency coil.

In a further embodiment, a transmitting high-frequency coil may include multiple coil conductors and at least one of the coil conductors may be made up of a first high-frequency shield with which the outer surface of a PET detector is covered. For example, in a case where a transmitting high-frequency coil includes a coil conductor, which is formed in a ring, in addition to the two end rings, PET detectors covered with first high-frequency shields may be used for all of the multiple coil conductors. Furthermore, for a part of the coil conductors, PET detectors covered with first high-frequency shields may be used.

Furthermore, in the above-described embodiments, the PET-MRI apparatus may include at least two PET detectors and at least one of the multiple coil conductors may be made up of a first high-frequency shield with which at least one of the at least two PET detectors is covered. For example, when the PET-MRI apparatus includes two PET detectors, one of the PET detectors is covered with a first high-frequency shield and used as a coil conductor of a transmitting high-frequency coil and the other PET detector is provided independently of the transmitting high-frequency coil. The independently provided PET detector may be covered with or may not necessarily be covered with a first high-frequency shield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A PET-MRI apparatus comprising:
a static magnetic field magnet configured to generate a static magnetic field;
a gradient coil configured to apply a gradient magnetic field to a subject placed in the static magnetic field;
a high-frequency coil configured to apply a high-frequency magnetic field to the subject and detect a magnetic resonance signal emitted from the subject in response to application of the high-frequency magnetic field and the gradient magnetic field;
an MR image reconstruction unit configured to reconstruct an MR image based on the magnetic resonance signal detected by the high-frequency coil;
a PET detector having a ring shape and configured to detect a gamma ray emitted from a positron-emitting radionuclide injected into the subject; and
a PET image reconstruction unit configured to reconstruct a PET image from projection data generated based on the gamma ray detected by the PET detector,
wherein a coil conductor of the high-frequency coil is made up of a first high-frequency shield that covers the outer surface of the PET detector.

2. The PET-MRI apparatus according to claim 1, further comprising a second high-frequency shield arranged between the gradient coil and the high-frequency coil and configured to shield the high frequency generated by the high-frequency coil.

3. The PET-MRI apparatus according to claim 1, wherein the high-frequency coil includes a plurality of coil conductors and at least one of the coil conductors is made up of the first high-frequency shield that covers the outer surface of the PET detector.

4. The PET-MRI apparatus according to claim 3, comprising at least two PET detectors,
wherein at least one of the coil conductors is made up of a first high-frequency shield that covers at least one of the at least two PET detectors.

5. The PET-MRI apparatus according to claim 4, wherein
at least two of the at least two PET detectors are arranged such that a magnetic field center of the static magnetic field is between the PET detectors, and
at least two of the coil conductors are made up of two first high-frequency shields that cover the two PET detectors, which are arranged such that the magnetic field center is between the PET detectors.

6. The PET-MRI apparatus according to claim 4, wherein the high-frequency coil is a bird cage coil that is formed to be approximately cylindrical and at least one of two end rings of the bird cage coil is made up of the first high-frequency shield that covers one of the at least two PET detectors.

7. A PET-MRI apparatus comprising:
a static magnetic field magnet configured to generate a static magnetic field;
a gradient coil configured to apply a gradient magnetic field to a subject;
a transmitting high-frequency coil configured to apply a high-frequency magnetic field to the subject placed in the static magnetic field;
a receiving high-frequency coil configured to detect a magnetic resonance signal emitted from the subject in response to application of the high-frequency magnetic field and the gradient magnetic field;
an MR image reconstruction unit configured to reconstruct an MR image based on the magnetic resonance signal detected by the receiving high-frequency coil;
a PET detector having a ring shape and configured to detect a gamma ray emitted from a positron-emitting radionuclide injected into the subject; and
a PET image reconstruction unit configured to reconstruct a PET image from projection data generated based on the gamma ray detected by the PET detector,
wherein at least one of a coil conductor of the transmitting high-frequency coil and a coil conductor of the receiving high-frequency coil is made up of a high-frequency shield that covers the outer surface of the PET detector.

8. The PET-MRI apparatus according to claim 7, further comprising a second high-frequency shield arranged between the gradient coil and the transmitting high-frequency coil and configured to shield the high frequency generated by the transmitting high-frequency coil.

9. The PET-MRI apparatus according to claim 7, wherein the transmitting high-frequency coil includes a plurality of coil conductors and at least one of the coil conductors is made up of the first high-frequency shield that covers the outer surface of the PET detector.

10. The PET-MRI apparatus according to claim 9, comprising at least two PET detectors,
wherein at least one of the coil conductors is made up of a first high-frequency shield that covers at least one of the at least two PET detectors.

11. The PET-MRI apparatus according to claim 10, wherein
at least two of the at least two PET detectors are arranged such that a magnetic field center of the static magnetic field is between the PET detectors, and
at least two of the coil conductors are made up of two first high-frequency shields that cover the two PET detectors, which are arranged such that the magnetic field center is between the PET detectors.

12. The PET-MRI apparatus according to claim 10, wherein the transmitting high-frequency coil is a bird cage coil that is formed to be approximately cylindrical and at least one of two end rings of the bird cage coil is made up of the first high-frequency shield that covers one of the at least two PET detectors.

13. The PET-MRI apparatus according to claim 1, where the PET detector converts the gamma ray to an analog signal and outputs the analog signal, the PET-MRI apparatus further comprising:
a signal amplifier configured to amplify the analog signal output from the PET detector;
a first signal converter configured to convert the analog signal amplified by the signal amplifier;
a second signal converter configured to convert the digital signal, which is obtained by the first signal converter, to an optical signal; and
an optical fiber that transfers the optical signal obtained by the second signal converter,
wherein the first high-frequency shield is formed so as to cover the signal amplifier, the digital signal converter, and the optical signal converter in addition to the PET detector.

14. The PET-MRI apparatus according to claim 1, wherein the first high-frequency shield has a slit.

15. The PET-MRI apparatus according to claim 1, further comprising a cooling unit provided on the outer surface or the inner side of the first high-frequency shield.
